(19) United States
(12) Patent Application Publication
(10) Pub. No.: US 2024/0192599 A1
(43) Pub. Date: Jun. 13, 2024

(54) PHOTO-DEFINABLE HYDROPHOBIC COMPOSITIONS

(71) Applicant: Hewlett-Packard Development Company, L.P., Spring, TX (US)

(72) Inventors: Bo Song, Corvallis, OR (US); Chien-Hua Chen, Corvallis, OR (US); Michael G. Groh, Corvallis, OR (US)

(73) Assignee: Hewlett-Packard Development Company, L.P., Spring, TX (US)

(21) Appl. No.: 18/554,774

(22) PCT Filed: Apr. 15, 2021
(86) PCT No.: PCT/US2021/027434

§ 371 Date: Oct. 10, 2023

(51) Int. Cl. G03F 7/075; B41J 2/16; C08L 83/06; G03F 7/00; G03F 7/038; G03F 7/16; G03F 7/20

(52) U.S. Cl. CPC G03F 7/0757; B41J 2/1606; B41J 2/1631; B41J 2/1645; C08L 83/06; G03F 7/0035; G03F 7/0385; G03F 7/162; G03F 7/168; G03F 7/2002; G03F 7/2022

(57) ABSTRACT

A photo-definable hydrophobic composition (“composition”) is presented. The composition can include from about 0.01 wt % to about 20 wt % of a polyether modified siloxane and from about 80 wt % to about 99.99 wt % of a polymeric photoresist. The polymeric photoresist can be selected from an epoxy-based photoresist, a bisbenzocyclobutene-based photoresist, a polyimide-based photoresist, a polybenzoxazole-based photoresist, a polyimide-polybenzoxazole-based photoresist, an admixture, or a combination thereof.

### BACKGROUND

Controlling and manipulating fluids on a small scale in areas where surface forces may dominate volumetric forces occurs in microfluidic devices. Microfluidic devices are used in many areas including research sciences, medical diagnostics, chemical sensing, electronics, printing, and the like. As the variety of available uses for microfluidic devices increases, so does the demand for different materials used in the creation of those devices.

### BRIEF DESCRIPTION OF THE DRAWINGS

FIG. 1 graphically illustrates a portion of an example microfluidic device in accordance with the present disclosure;

FIG. 2 graphically illustrates a portion of an example microfluidic device in accordance with the present disclosure;

FIG. 3 graphically illustrates a portion of an example microfluidic device in accordance with the present disclosure; and

FIG. 4 is a flow diagram of an example method of applying a photo-definable hydrophobic composition to a microfluidic device in accordance with the present disclosure.

### DETAILED DESCRIPTION

The present disclosure describes photo-definable hydrophobic compositions that can be used in microfluidic devices. Microfluidic devices can manipulate fluids on a small scale and the fluid physics can generally be different from what occurs in macroscopic fluid devices. For example, in microfluidic devices surface tension can be a predominant force, whereas surface tension can be unimportant in macroscopic fluidic devices. Further in microfluidic devices, gravitational forces and fluid turbulence can be negligible due to the fact that an amount of fluids utilized therein can be very small. Generally, fluid flow in microfluidic devices can be driven by pressure gradients applied via external reservoirs, pressure driven flow generated by peristaltic pumps on the device, and externally applied electric fields. Capillary, acoustic, and magnetic forces have also been used to move fluids in microfluidic devices.

In accordance with this, a photo-definable hydrophobic composition (“composition”) can include from about 0.01 wt % to about 20 wt % of a polyether modified siloxane and from about 80 wt % to about 99.99 wt % of a polymeric photoresist. In an example, the polyether modified siloxane can be selected from a siloxane with a polyether functional group attached thereto where the polyether functional group can include functional groups selected from alkyl, ethylene oxide, propylene oxide, or a combination thereof; a polydimethylsiloxane with a polyether functional group attached thereto; polyether-siloxane; or a combination thereof. In another example, the polymeric photoresist can include an epoxy-based photoresist, a bisbenzocyclobutene-based photoresist, a polyimide-based photoresist, a polybenzoxazole-based photoresist, a polyimide-polybenzoxazole-based photoresist, an admixture, or a combination thereof. In yet another example, the composition can include hydrogen bonds, dipole-dipole interactions, dispersion forces, or a combination thereof between the polyether modified siloxane and the polymeric photoresist. In a further example, the polyether modified siloxane can be present at from about 0.01 wt % to about 5 wt % and the polymeric photoresist can be present at from about 95 wt % to about 99.99 wt %. In one example, the photo-definable hydrophobic composition can have a photo-definable resolution of from about 0.1 μm to about 10 μm.

Also disclosed herein is a microfluidic device (“device”). The device can include a hydrophilic substrate of a hydrophilic material having a water contact angle from about 50° to about 90°, a first fluid interface region including the hydrophilic material exposed at the first fluid interface region, and a second fluid interface region including a photo-definable hydrophobic composition applied on the hydrophilic material at the second fluid interface region The photo-definable hydrophobic composition can include a polyether modified siloxane admixed with a polymeric photoresist. The photo-definable hydrophobic composition can have a water contact angle from about 91° to about 150°. A differential between the water contact angle of the hydrophilic material at the first fluid interface region and the water contact angle of the photo-definable hydrophobic composition at the second fluid interface region can be from about 20° to about 80°. In one example, the first fluid interface region and the second fluid interface region can be positioned along separate portions of an interior wall of a microfluidic channel. At a location within the microfluidic channel where the first fluid interface region abuts the second fluid interface region, a fluidic mixing region can be formed when fluid is flowed through the microfluidic channel. In another example, the device can further include an electrode positioned at the second fluid interface region of the microfluidic channel. In yet another example, the microfluidic device can be an inkjet printhead and the first fluid interface region can define an opening of an ejection port and the second fluid interface region can be located outside of and around the opening. In a further example, the second fluid interface region can form a counter bore around the ejection port of the inkjet printhead.

In another example, a method of applying a photo-definable hydrophobic composition to a microfluidic device (“method”) can include admixing a polyether modified siloxane and a polymeric photoresist to form a photo-definable hydrophobic composition, applying the photo-definable hydrophobic composition to a hydrophilic surface of a hydrophilic material, applying a photoresist mask over a selected area of the photo-definable hydrophobic composition, exposing the microfluidic device to ultraviolet radiation, wherein an area of the photo-definable hydrophobic composition becomes crosslinked with exposure to the ultraviolet radiation, and removing the photoresist mask and uncrosslinked photo-definable hydrophobic composition from the hydrophilic surface. In one example, the method can further include baking the microfluidic device after exposing the microfluidic device to ultraviolet radiation to cure crosslinked photo-definable hydrophobic composition. In another example, applying the photo-definable hydrophobic composition can include spin coating the photo-definable hydrophobic composition onto a hydrophilic surface of the microfluidic device at from about 500 rpms to about 3,000 rpms for about 15 seconds to about 60 seconds, or dry film laminating the photo-definable hydrophobic composition onto a hydrophilic surface of the microfluidic device at a temperature that can range from about 70° C. to about 100° C. and a pressure that can range from about 10 psi to about 50 psi. In yet another example, applying the photoresist mask and exposing the microfluidic device to the ultraviolet radiation can be repeated, and can include applying a first photoresist mask, exposing the microfluidic device to the ultraviolet radiation, and post exposure baking the microfluidic device at from about 70° C. to about 120° C. for about 30 seconds to about 10 minutes; and applying a second photoresist mask smaller than the first photoresist mask, exposing the microfluidic device to the ultraviolet radiation, and baking the microfluidic device at from about 150° C. to about 200° C. for about 15 minutes to about 1 hour.

It is noted that when discussing the photo-definable hydrophobic composition, the microfluidic device, and/or the method of applying photo-definable hydrophobic composition to a microfluidic device herein, these discussions can be considered applicable to one another whether or not they are explicitly discussed in the context of that example. Thus, for example, when discussing a polymeric photoresist related to the photo-definable hydrophobic composition, such disclosure is also relevant to and directly supported in the context of the microfluidic device, the method of applying photo-definable hydrophobic composition to a microfluidic device, and vice versa.

It is also understood that terms used herein will take on the ordinary meaning in the relevant technical field unless specified otherwise. In some instances, there are terms defined more specifically throughout the specification or included at the end of the present specification, and thus, these terms can have a meaning as described herein.

### Photo-Definable Hydrophobic Composition

A photo-definable hydrophobic composition, referred to herein as a “composition”, can include an admixture of from about 0.01 wt % to about 20 wt % of a polyether modified siloxane and from about 80 wt % to about 99.99 wt % of a polymeric photoresist.

The polyether modified siloxane, in further detail, can be present at from about 0.1 wt % to about 15 wt %, from about 5 wt % to about 20 wt %, from about 5 wt % to about 15 wt %, from about 0.01 wt % to about 5 wt %, or from about 0.5 wt % to about 2 wt %. The polyether modified siloxane can include a siloxane with a polyether functional group attached thereto, where the polyether functional group can include functional groups selected from alkyl, ethylene oxide, propylene oxide, or a combination thereof; a polydimethylsiloxane with a polyether functional group attached thereto; polyether-siloxane; or a combination thereof. In another example, the polyether modified siloxane can include polydimethylsiloxane with a polyether functional group attached thereto, a polyether-siloxane, or a combination thereof. In yet another example, the polyether modified siloxane can include a polydimethylsiloxane with a polyether functional group attached thereto.

The polymeric photoresist can be present at from about 80 wt % to about 99 wt %, from about 85 wt % to about 95 wt %, from about 90 wt % to about 99.99 wt %, from about 80 wt % to about 90 wt %, or from about 95 wt % to about 99.99 wt %. The polymeric photoresist can include an epoxy-based photoresist, a bisbenzocyclobutene-based photoresist, a polyimide-based photoresist, a polybenzoxazole-based photoresist, a polyimide-polybenzoxazole-based photoresist, an admixture, or a combination thereof. In one example, the polymeric photoresist can include an epoxy-based photoresist. The epoxy-based photoresist can be selected from SU-8 commercially available from Kayaku Advanced Materials® Inc., USA; MEGAPOSIT™ SPR™ 220 commercially available from Rohm and Haas Electronic Materials, LLC, USA; AZ® 4500 Series, such as AZ® 4533 and AZ® 4562, commercially available from MicroChemicals GmbH, UK; SUEX® and ADEX™ commercially available from DJ Microlaminates Inc., Germany; and HARE-SQ commercially available from KemLab, USA. In yet other examples, the polymeric photoresist can include a bisbenzocyclobutene-based photoresist. Commercially available examples can include Cylocotene®, such as the 3000 series, 4000 series, 6505, and XUS 35077, from the Dow Chemical Company, USA In another example, the polymeric photoresist can include a polyimide. A commercially available example can include Pyralin and HD4011 commercially available from HD Microesystems™ USA. In a further example, the polymeric photoresist can include polybenzoxazole-based photoresist. Commercially available examples can include Pimel™ AM-270 Series, Pimel™ MA-1000 Series, Pimel™ I-8000 series, Pimel™ BL-300 Series, and Pimel™ BM-300 Series, all available from Asahi Kasei Corporation, Japan.

The polymeric photoresist may be a positive photoresist or a negative photoresist. A positive photoresist becomes soluble to a photoresist developer when exposed to ultraviolet radiation. Example positive photoresists can include MEGAPOSIT™ SPR™ 220 commercially available from Rohm and Haas Electronic Materials, LLC, USA; AZ® 4500 Series, such as AZ® 4533 and AZ® 4562, commercially available from MicroChemicals GmbH, UK; HARE-SQ commercially available from KemLab, USA; and Pimel™ AM-270 Series and Pimel™ MA-100 Series, both available from Asahi Kasei Corporation, Japan. A negative photoresist cross-links and becomes insoluble to a photoresist developer when exposed to ultraviolet radiation. Example negative photoresists can include SU-8 commercially available from Kayaku Advanced Materials® Inc., USA; SUEX® and ADEX™ commercially available from DJ Microlaminates Inc., Germany; and Pimel™ I-8000 series, Pimel™ BL-300 Series, and Pimel™ BM-300 Series, all available from Asahi Kasei Corporation, Japan. In one example, the polymeric photoresist can be a negative photoresist.

The polyether modified siloxane and the polymeric photoresist can interact with one another in the composition. In an example, the photo-definable polymeric composition can include Van der Waals forces such as hydrogen bonds, dipole-dipole interactions, dispersion forces, or any combinations thereof between the polyether modified siloxane and the polymeric photoresist. In an example, interactions between the polyether modified siloxane and the polymeric photoresist can include hydrogen bonds. In another example, interactions between the polyether modified siloxane and the polymeric photoresist can include dipole-dipole interactions. In a further example, the interactions between the polyether modified siloxane and the polymeric photoresist can include dispersion forces.

The incorporation of the polyether modified siloxane into the polymeric photoresist can alter the surface energy of the polymeric photoresist and form a low surface energy photo-definable hydrophobic composition. A surface energy of the hydrophobic composition can be characterized by a water contact angle of a surface of a layer of the hydrophobic composition. In some examples, a water contact angle of a surface of a layer of the hydrophobic composition can be from about 91° to about 150°, from about 95° to about 105°, from about 91° to about 115°, from about 95° to about 125°, from about 100° to about 125°, or from about 125° to about 150°. Water contact angle can be measured by an optical tensiometer. The optical tensiometer can dispense a 0.1 μL water drop on a layer of the composition, a digital camera can take an image of the droplet on the surface, and the contact angle of the droplet with respect to the surface of the outermost layer can be digitally measured. A water contact angle can be measured according to ASTM D7334 standard.

In yet other examples, a low surface energy of the composition can be measured using an ink contact angle. The ink contact angle can be based on a latex ink composition. In an example, the ink contact angle can range from about 30° to about 60°, from about 30° to about 45° from about 40° to about 50°, from about 45° to about 60°, or from about 50° to about 60°. The ink contact angle can be measured by an optical tensiometer. The optical tensiometer can dispense a 0.1 μL drop of a latex ink, commercially available as HP® 792 Latex Magenta or HP® 831 Latex series, on a layer of the hydrophobic composition, a digital camera can take an image of the droplet on the surface, and the contact angle of the droplet with respect to the surface of the outermost layer can be digitally measured.

The hydrophobic composition can be photo-definable. The photo-definable nature of the composition can permit high resolution of the hydrophobic composition when applied to a surface. In an example, the photo-definable composition can have a photo-definable resolution of from about 0.1 μm to about 10 μm, from about 0.1 μm to about 5 μm, from about 5 μm to about 10 μm, from about 0.5 μm to about 2.5 μm, from about 2.5 μm to about 7.5 μm, or from about 1 μm to about 3 μm.

### Microfluidic Devices

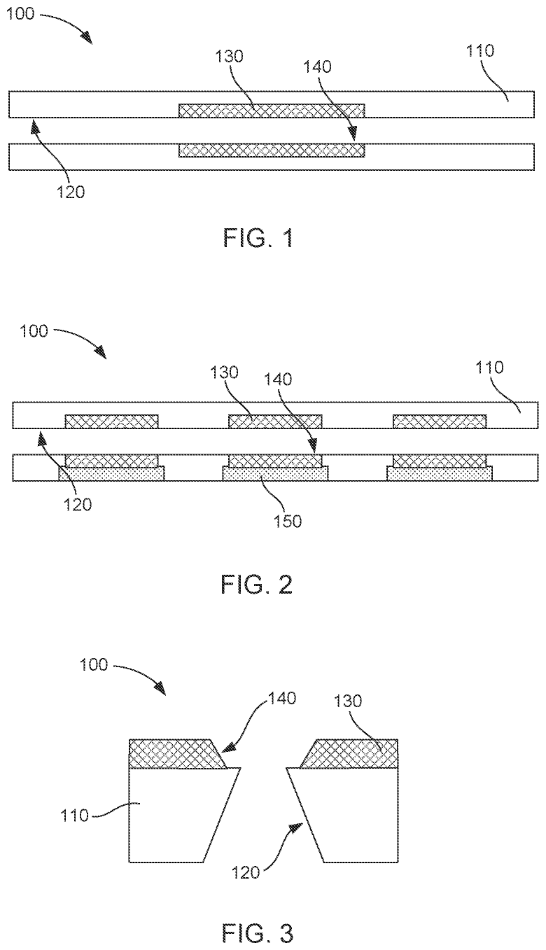

Further presented herein are microfluidic devices. A microfluidic device 100, as indicated in FIG. 1, can include a hydrophilic substrate 110 of a hydrophilic material, with the surface having a water contact angle from about 50° to about 90°, a first fluid interface region 120 including the hydrophilic material exposed at the first fluid interface region, and a second fluid interface region 140 including a photo-definable hydrophobic composition 130 applied on the hydrophilic material at the second fluid interface region. The photo-definable hydrophobic composition can include a polyether modified siloxane admixed with a polymeric photoresist and the photo-definable hydrophobic composition can have a water contact angle from about 91° to about 150°.

A differential between the water contact angle of the hydrophilic material at the first fluid interface region and the water contact angle of the photo-definable hydrophobic composition at the second fluid interface region can be from about 20° to about 80°. Incorporating both a hydrophilic material and a photo-definable hydrophobic composition can provide different surface tensions in different areas of the microfluidic device. Aqueous fluids may flow with ease in areas including the hydrophilic material, while aqueous fluid may be repealed in areas including the photo-definable hydrophobic composition. Therefore, aqueous fluids may require greater force to flow into and through areas including the photo-definable hydrophobic composition. Positioning of these materials can create fluid interfaces that can define mixing zones for fluids and/or define pathways for fluid flow. The differences in surface tensions of the hydrophilic material and the photo-definable hydrophobic composition can be used to control fluid flows in microfluidic devices.

The hydrophilic substrate, which typically includes a hydrophilic surface, may be formed of and/or coated with a hydrophilic material. The hydrophilic material can be selected from SU8, silica, fused silica, silicon, quartz, glass, polystyrene, polycarbonate, polymethyl methacrylate, polyethylene glycol, polyethylene glycol diacrylate, polyimide, polyfluoropolyether diol methacrylate, bisbenzocyclobutene, polyurethane, cyclic-olefin copolymers, copolymers, or combinations thereof. The hydrophilic material can have a water contact angle at a surface thereof that can range from about 50° to about 90°, from about 60° to about 80°, from about 70° to about 90°, from about 70° to about 80° from about 80° to about 90°, or from about 75° to about 85°. Water contact angle may be determined as described above. The hydrophilic substrate can have an ink contact angle at a surface thereof that can range from about 5° to about 30°, from about 5° to about 15°, from about 10° to about 25°, from about 15° to about 25°, or from about 25° to about 30°. The ink contact angle can be determined as described above. The hydrophilic substrate can form a surface of the microfluidic device, can be applied as a coating over a surface of the microfluidic device, or can be embedded as a coating into a surface of the microfluidic device.

The hydrophilic substrate can be exposed at a first fluid interface region. The first fluid interface region can vary based on the microfluidic device. For example, in a microfluidic device that includes microfluidic channels, the first fluid interface region may be located along a portion of the microfluidic channel, as illustrated in FIGS. 1 and 2. In fluid ejection devices, the first fluid interface region can be located along an opening of an ejection port, as illustrated in FIG. 3 hereinafter.

The photo-definable hydrophobic composition can be as described above. The photo-definable hydrophobic composition from a surface of the microfluidic device can be applied as a coating over a surface of the microfluidic device or can be embedded as a coating into a surface of the microfluidic device. The photo-definable hydrophobic composition can be exposed at a second fluid interface region of the microfluidic device.

In some devices, the second fluid interface region may be located along a portion of the microfluidic channel, as illustrated in FIGS. 1 and 2. At an area where the hydrophilic substrate and the hydrophobic composition abut, a fluidic mixing region can be formed. Fluid with greater pressure may flow through the second fluid interface region while fluid with less pressure may be inhibited from flowing there through due to the hydrophobic composition. Accordingly, a junction between the first fluid interface region and the second fluid interface region can allow for mixing and/or can allow for division of components where a branch in microfluidic channels may occur and can thereby direct fluid flow. In some examples, microfluidic devices including microfluidic channels can further include a voltage source 150, such as an electrode beneath the second fluid interface region as illustrated in FIG. 2. Fluid may bead up as droplets on the hydrophobic composition and applying a voltage can change the wettability of the droplets thereby moving the droplets.

In yet other examples, the microfluidic device can be an inkjet printhead. An ejection port of an inkjet printhead is illustrated in FIG. 3. The first fluid interface region 120 can define an opening of an ejection port and the second fluid interface region 130 can be located outside of and around the opening. In some examples, the second fluid interface region can be applied on a counter bore around the ejection port of the inkjet printhead. The hydrophobic composition 130 can prevent ink puddling and drooling at the ejection port, while the hydrophilic substrate 110 including a hydrophilic material can allow ink to flow freely through the ejection port. In addition, the hydrophobic coating can prevent ink caking at the inkjet printhead thereby reducing inkjet printhead damage.

### Methods of Applying a Photo-Definable Hydrophobic Compositions to Microfluidic Devices

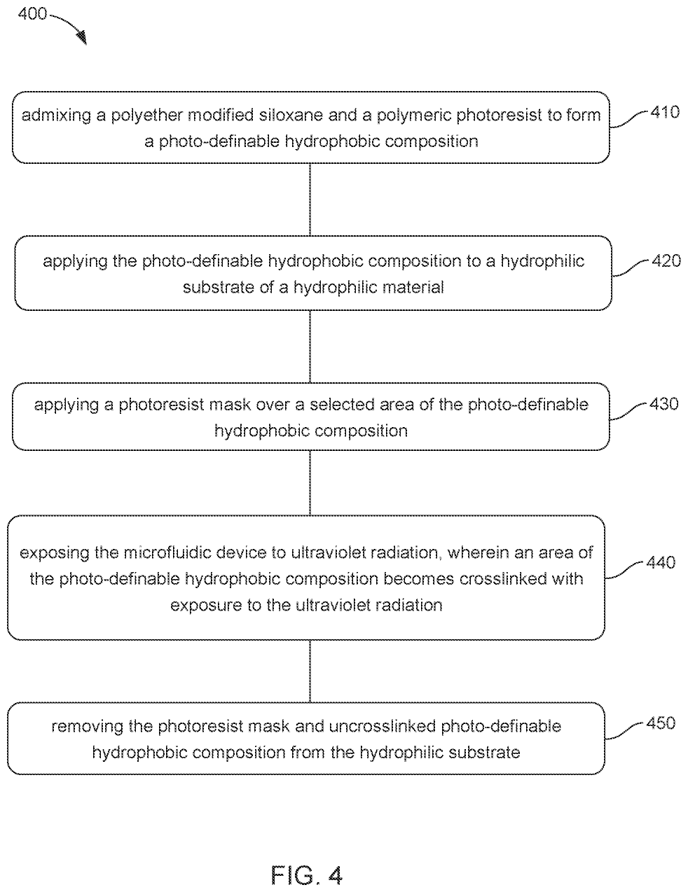

Further presented herein is a method of applying a photo-definable hydrophobic composition to a microfluidic device. The method 400, as illustrated in FIG. 4, can include admixing 410 a polyether modified siloxane and an polymeric photoresist to form a photo-definable hydrophobic composition; applying 420 the photo-definable hydrophobic composition to a hydrophilic substrate of a hydrophilic material; applying 430 a photoresist mask over a selected area of the photo-definable hydrophobic composition; exposing 440 the microfluidic device to ultraviolet radiation where an area of the photo-definable hydrophobic composition can become crosslinked upon exposure to ultraviolet radiation; and removing 450 the photoresist mask and uncrosslinked photo-definable hydrophobic composition from the hydrophilic surface. The polyether modified siloxane, the polymeric photoresist, and the hydrophilic substrate can be as described above.

The admixing in further detail can include adding an amount of the polyether modified siloxane and the polymeric photoresist together and admixing via shear force mixing. In some examples, the admixing can occur for a period of time ranging from about 1 hour to about 36 hours, from about 1 hour to about 12 hours, from about 12 hours to about 24 hours, from about 24 hours to about 36 hours, from about 1 hour to about 5 hours, from about 10 hours to about 20 hours, or from about 25 hours to about 35 hours. The admixing may occur at room temperature (about 20° C. to about 25° C.) or may occur at an elevated temperature. For example, the admixing can occur at from about 20° C. to about 50° C., from about 20° C. to about 30° C., from about 20° C. to about 40° C., or from about 40° C. to about 50° C. Heat may be applied from above or below the admixture during admixing.

Following admixing, the photo-definable hydrophobic composition can be applied to a hydrophilic substrate of a hydrophilic material. The applying can include spin coating, spray coating, slit coating, bar coating, or dry film laminating of the photo-definable hydrophobic composition onto the hydrophilic substrate. Spin coating can include depositing an amount of the photo-definable hydrophobic composition on the hydrophilic substrate followed by rotating the hydrophilic substrate to dispense the photo-definable hydrophobic composition via centrifugal force over a surface of the hydrophilic substrate. An amount of the photo-definable hydrophobic composition deposited can vary based on a desired thickness of the hydrophobic composition. In one example, the spin coating may occur at from about 500 rpms to about 3,000 rpms for about 15 seconds to about 60 seconds. In yet other examples, the spin coating may occur at from about 500 rpms to about 2,500 rpms, from about 1,000 rpms to about 3,000 rpms, from about 1,500 rpms to about 3,000 rpms, or from about 2,000 rpms to about 3,000 rpms. In further examples, the spin coating may occur from about 15 seconds to about 45 seconds, from about 15 seconds to about 30 seconds, from about 30 seconds to about 45 seconds, from about 30 seconds to about 60 seconds, or from about 20 seconds to about 40 seconds.

Dry film laminating of the photo-definable hydrophobic composition onto a hydrophilic surface of the microfluidic device can occur at a temperature ranging from about 70° C. to about 100° C. and a pressure ranging from about 10 psi to about 50 psi. In some examples, the temperature can range from about 70° C. to about 90° C., from about 80° C. to about 100° C., or from about 75° C. to about 95° C. In some examples, the pressure can range from about 10 psi to about 30 psi, from about 25 psi to about 50 psi, from about 20 psi to about 40 psi, or from about 30 psi to about 50 psi. The temperature and pressure can vary depending on the thickness of the photo-definable hydrophobic composition being applied.

Following application of the photo-definable hydrophobic composition, a photoresist mask can be applied over a selected area of the photo-definable hydrophobic composition. The photoresist mask may include an opaque plate with holes or transparent sections that can allow ultraviolet radiation to pass through the photoresist mask in a defined pattern. The photoresist mask can be a template which can include openings where the hydrophobic composition may remain or may be removed from the hydrophilic substrate. Whether or not the openings align with portions to remain or to be removed may depend on the polymeric photoresist in the photo-definable hydrophobic composition. If the polymeric photoresist is a positive photoresist, then the portion of the polymeric photoresist exposed to ultraviolet radiation may become soluble to a photoresist developer where the unexposed portion remains insoluble. If the polymeric photoresist is a negative photoresist, then the portion of the polymeric photoresist exposed to ultraviolet radiation cross-links and becomes insoluble to a photoresist developer, whereas the unexposed portions can be removed by the photoresist developer. The photoresist mask may include fused silica covered with an opaque film, glass covered with an opaque film, silicon and molybdenum, or the like.

Once the photoresist mask is applied over the photo-definable hydrophobic composition, the microfluidic device can be exposed to ultraviolet radiation. The exposure can vary depending on the polymeric photoresist. In some examples, the ultraviolet radiation can have a wavelength ranging from about 100 nm to about 450 nm, from about 100 nm to about 280 nm, from about 280 nm to about 315 nm, from about 315 nm to about 400 nm, from about 100 nm to about 300 nm, or from about 200 nm to about 450 nm. The exposure time frame can range from about 30 seconds to about 1 hour, from about 5 minutes to about 45 minutes, or from about 30 minutes to about 1 hour. As previously indicated, a portion of the photo-definable hydrophobic composition may become crosslinked following exposure to the ultraviolet radiation.

Following exposure to ultraviolet radiation, the photoresist mask and uncrosslinked portions of the photo-definable hydrophobic composition can be removed. In some examples, a photoresist developer can be applied to remove portions of the hydrophobic composition that may not be crosslinked. The photoresist developer may vary depending on the polymeric photoresist in the photo-definable hydrophobic composition.

In some examples, the method can further include baking the microfluidic device after exposing the microfluidic device to ultraviolet radiation to cure the crosslinked photo-definable hydrophobic composition. The baking can include a post exposure bake (PEB) and/or a curing bake. A PEB can occur when multiple photoresist masks may be applied in order to form a layer of the photo-definable hydrophobic composition with depth variations. A PEB can include baking at a temperature ranging from about 70° C. to about 120° C., from about 80° C. to about 100° C., from about 70° C. to about 90° C., or from about 100° C. to about 120° C. Post exposure baking can occur for a period of time ranging from about 30 seconds to about 10 minutes, from about 2 minutes to about 8 minutes, from about 1 minute to about 5 minutes, or from about 5 minutes to about 10 minutes. A curing bake can be a final bake. The curing bake can occur at from about 150° C. to about 200° C., from about 150° C. to about 175° C. from about 160° C. to about 180° C., or from about 180° C. to about 200° C. The curing bake can occur for a period of time ranging from about 15 minutes to about 1 hour, from about 15 minutes to about 45 minutes, from about 15 minutes to about 30 minutes, or from about 30 minutes to about 1 hour.

In some examples, when the photo-definable hydrophobic composition on the microfluidic device includes depth variations, applying the photoresist mask and exposing the microfluidic device to the ultraviolet radiation may be repeated. The method can include applying a first photoresist mask, exposing the microfluidic device to the ultraviolet radiation, and soft baking at from about 70° C. to about 120° C. for a period of time of about 30 seconds to about 10 minutes. Following the first application, exposure, and PEB, a second photoresist mask smaller than the first photoresist mask can be applied. Then the microfluidic device can be exposed to the ultraviolet radiation, and an additional baking of the microfluidic device can occur at from about 150° C. to about 200° C. for a period of time of about 15 minutes to about 1 hour.

A multi-step photoresist process can include masking, exposure, baking, etc., and can be used to form a counter bore around the ejection port of the inkjet printhead. In some examples, the counter bore can have a tapered shape. Tapering can occur by incorporating a lower exposure time during the first photoresist mask, PEB at lower temperatures, and for less periods of time, or combinations thereof. As used, “lower exposure time,” “lower temperatures,” and “less periods of time” indicate the bottom end of the ranges discussed above. Accordingly, a portion of the photo-definable hydrophobic composition exposed near an exterior surface may be processed, while an interior most portion (adjacent or near the hydrophilic substrate) may not be processed; thereby, permitting widening during development of the interior most portion of the photo-definable hydrophobic composition.

The photo-definable hydrophobic composition can have a photo-definable resolution of from about 0.1 μm to about 10 μm, from about 0.1 μm to about 5 μm, from about 5 μm to about 10 μm, from about 0.5 μm to about 2.5 μm, from about 2.5 μm to about 7.5 μm, or from about 1 μm to about 3 μm. The high resolution of the photo-definable hydrophobic composition can allow for the creation of well-defined features in or on microfluidic devices such as pillars, dots, channels, pitches, bores, or the like.

### Definitions

As used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 10%, or, in one aspect within 5%, of a stated value or of a stated limit of a range. The term “about” when modifying a numerical range includes as one numerical subrange a range defined by the exact numerical value indicated, e.g., the range of about 1 wt % to about 5 wt % includes 1 wt % to 5 wt % as an explicitly supported sub-range.

As used herein, a plurality of items, structural elements, compositional elements, and/or materials may be presented in a common list for convenience. However, these lists should be construed as though an individual member of the list is also identified as a separate and unique member. Thus, no individual member of such list should be construed as a de facto equivalent of any other member of the same list based on presentation in a common group without indications to the contrary.

Concentrations, dimensions, amounts, and other numerical data may be presented herein in a range format. A range format is used merely for convenience and brevity and should be interpreted flexibly to include the numerical values explicitly recited as the limits of the range, as well as to include all the individual numerical values or sub-ranges encompassed within that range as the individual numerical value and/or sub-range is explicitly recited. For example, a weight ratio range of about 1 wt % to about 20 wt % should be interpreted to include the explicitly recited limits of 1 wt % and 20 wt % and to include individual weights such as about 2 wt %, about 11 wt %, about 14 wt %, and sub-ranges such as about 10 wt % to about 20 wt %, about 5 wt % to about 15 wt %, etc.

### EXAMPLES

The following examples illustrate the technology of the present disclosure. However, it is to be understood that the following are merely illustrative of the photo-definable hydrophobic composition, the microfluidic device, and/or the method of applying photo-definable hydrophobic composition to a microfluidic device herein. Numerous modifications and alternative methods may be devised without departing from the present disclosure. Thus, while the technology has been described above with particularity, the following provides further detail in connection with what are presently deemed to be the acceptable examples. Additional method step elements illustrated in the examples are provided by way of example and can be practiced with or without these additional elements.

### Example 1—Preparing a Photo-Definable Hydrophobic Composition and Contact Angle Testing

Two photo-definable hydrophobic compositions were prepared by admixing SU-8 commercially available from Kayaku Advanced Materials® Inc., USA with a polyether modified siloxane, at amounts indicated in the table below. The admixing occurred continually for a period of time of about 48 hours, at a shear mixing rate of 20 rpms, and a temperature of about 25° C.

TABLE 1
Admixtures

| Photo-Definable | | |
|---|---|---|
| Hydrophobic Composition | SU-8 | BYK |

| | | | | |
|---|---|---|---|---|
| Composition A | 99 | wt % | 1 | wt % |
| Composition B | 99.9 | wt % | 0.1 | wt % |

The compositions were applied at a thickness of about 10 μm on a 20 μm thick slide of SU-8, exposed to ultraviolet radiation having a wavelength of about 365 nm for a period of time of about 30 seconds, and baked at a temperature of about 170° C. for a time period of about 30 minutes. Water and ink contact angles for the compositions were tested by an optical tensiometer. The optical tensiometer dispensed a 0.1 μL water drop or a 0.1 μL of ink on an SU-8 substrate or the layer of the hydrophobic composition on an SU-8 substrate, a digital camera took an image of the droplet on the surface, and the contact angle of the droplet with respect to the surface of the outermost layer was digitally measured. The measurements occurred according to ASTM D7334 standard. Water and Ink contact angles measured are indicated in Table 2 below. The inks tested included Ink A (commercially available as HP 63), Ink B (commercially available as HP 950), and Ink C (commercially available as HP 831).

TABLE 2
Contact Angles

| Substrate | Water | Ink A | Ink B | Ink C |
|---|---|---|---|---|
| SU-8 | 82 | 30 | 25 | 19 |
| Composition A | 107 | 61 | 46 | 41 |
| Composition B | 103 | 60 | 42 | 39 |

In addition, an ability of the composition to absorb various inks was also measured. The ability was measured by placing the substrate in a bath of ink having a temperature of 70° C. for four weeks. Absorption was determined based on a change in weight of the samples after the samples dried. All of the compositions had a weight change less than 0.5 wt % after soaking for 28 days. Following, this, the water contact angle of the materials was retested following the absorption testing above.

TABLE 3
Water Contact Angles Following Soak

| Substrate | Pre-Soak | Post Soak |
|---|---|---|
| SU-8 | 82 | 80 |
| Composition A | 107 | 105 |
| Composition B | 103 | 102 |

The change in water contact angle following the soak was slightly lower but negligible.

### Example 2—Photo-Definability Testing

Composition B was spun coated onto several 20 μm thick SU-8 substrates. The spin coating involved depositing 5 mL of the photo-definable hydrophobic composition on an SU-8 substrate followed by rotating the SU-8 substrate to distribute Composition B via centrifugal force over the substrate. The spin coating occurred at about 2500 rpms for about 30 seconds. Following spin coating, a photoresist mask of glass with a thin chrome layer thereon was positioned over Composition B and a broad band UV from 365 to 405 nm of ultraviolet radiation was applied for about 30 seconds. The photoresist mask applied included patterning for arrows, pillars, and cross-hatching. A resolution ranging from about 10 μm to about 15 μm was achieved, depending on the pattern, and high adhesion of Composition B to the SU-8 substrate.

1. A photo-definable hydrophobic composition comprising:
from about 0.01 wt % to about 20 wt % of a polyether modified siloxane; and
from about 80 wt % to about 99.99 wt % of a polymeric photoresist.

2. The photo-definable hydrophobic composition of claim 1, wherein the polyether modified siloxane is selected from polydimethylsiloxane with a polyether functional group attached thereto; polyether-siloxane; a siloxane with a polyether functional group attached thereto, where the polyether functional group includes functional groups selected from alkyl, ethylene oxide, propylene oxide, or a combination thereof; or a combination thereof.

3. The photo-definable hydrophobic composition of claim 1, wherein the polymeric photoresist comprises an epoxy-based negative photoresist, bisbenzocyclobutene-based negative photoresist, a polyimide-based negative photoresist, a polybenzoxazole-based negative photoresist, a polyimide-polybenzoxazole-based negative photoresist, an admixture, or a combination thereof.

4. The photo-definable hydrophobic composition of claim 1, wherein hydrogen bonds, dipole-dipole interactions, dispersion forces, or a combination thereof are present between the polyether modified siloxane and the polymeric photoresist.

5. The photo-definable hydrophobic composition of claim 1, wherein the polyether modified siloxane is present at from about 0.01 wt % to about 5 wt % and the polymeric photoresist is present at from about 95 wt % to about 99.99 wt %.

6. The photo-definable hydrophobic composition of claim 1, wherein the photo-definable hydrophobic composition has a photo-definable resolution of from about 0.1 μm to about 10 μm.

7. A microfluidic device comprising:
a hydrophilic substrate of a hydrophilic material having a water contact angle from about 50° to about 90°;
a first fluid interface region including the hydrophilic material exposed at the first fluid interface region; and
a second fluid interface region including a photo-definable hydrophobic composition applied on the hydrophilic material at the second fluid interface region, wherein the photo-definable hydrophobic composition comprises a polyether modified siloxane admixed with a polymeric photoresist, and wherein photo-definable hydrophobic composition having a water contact angle from about 91° to about 150°,
wherein a differential between the water contact angle of the hydrophilic material at the first fluid interface region and the water contact angle of the photo-definable hydrophobic composition at the second fluid interface region is from about 20° to about 80°.

8. The microfluidic device of claim 7, wherein the first fluid interface region and the second fluid interface region are positioned along separate portions of an interior wall of a microfluidic channel, and wherein at a location within microfluidic channel where the first fluid interface region abuts the second fluid interface region, a fluidic mixing region is formed when fluid is flowed through the microfluidic channel.

9. The microfluidic device of claim 8, further comprising an electrode positioned at the second fluid interface region of the microfluidic channel.

10. The microfluidic device of claim 7, wherein the microfluidic device is an inkjet printhead and the first fluid interface region defines an opening of an ejection port and the second fluid interface region is located outside of and around the opening.

11. The microfluidic device of claim 10, wherein the second fluid interface region is applied on a counter bore around the ejection port of the inkjet printhead.

12. A method of applying photo-definable hydrophobic composition to a microfluidic device comprising:
admixing a polyether modified siloxane and a polymeric photoresist to form a photo-definable hydrophobic composition;
applying the photo-definable hydrophobic composition to a hydrophilic surface of a hydrophilic material;
applying a photoresist mask over a selected area of the photo-definable hydrophobic composition;
exposing the microfluidic device to ultraviolet radiation, wherein an area of the photo-definable hydrophobic composition becomes crosslinked with exposure to the ultraviolet radiation; and
removing the photoresist mask and uncrosslinked photo-definable hydrophobic composition from the hydrophilic surface.

13. The method of claim 12, further comprising baking the microfluidic device after exposing the microfluidic device to ultraviolet radiation to cure crosslinked photo-definable hydrophobic composition.

14. The method of claim 12, wherein applying the photo-definable hydrophobic composition includes:
spin coating the photo-definable hydrophobic composition onto the hydrophilic surface of the microfluidic device at from about 500 rpm to about 3,000 rpm for about 15 seconds to about 60 seconds; or
dry film laminating the photo-definable hydrophobic composition onto the hydrophilic surface of the microfluidic device at a temperature ranging from about 70° C. to about 100° C. and a pressure ranging from about 10 psi to about 50 psi.

15. The method of claim 12, wherein applying the photoresist mask and exposing of the microfluidic device to the ultraviolet radiation are repeated, and includes:
applying a first photoresist mask, exposing the microfluidic device to the ultraviolet radiation, and soft baking at from about 70° C. to about 120° C. for about 30 seconds to about 10 minutes; and
applying a second photoresist mask smaller than the first photoresist mask, exposing the microfluidic device to the ultraviolet radiation, and baking the microfluidic device at from about 150° C. to about 200° C. for about 15 minutes to about 1 hour.
